(19) United States
(12) Patent Application Publication
(10) Pub. No.: US 2009/0000818 A1
(43) Pub. Date: Jan. 1, 2009

(54) PERFORATED EMI GASKETS AND RELATED METHODS

(76) Inventor: Michael Poulsen, House Springs, MO (US)

Correspondence Address: HARNESS, DICKEY, & PIERCE, P.L.C, 7700 Bonhomme, Suite 400, ST. LOUIS, MO, 63105, US

(21) Appl. No.: 11/845,045

(22) Filed: Aug. 25, 2007

Related U.S. Application Data
(60) Provisional application No. 60/947,271, filed on Jun. 29, 2007.

(51) Int. Cl. H05K 9/00; H01S 4/00

(52) U.S. Cl. 174/370; 29/592.1

(57) ABSTRACT

According to various aspects, exemplary embodiments are provided of EMI shields, such as EMI gaskets. One exemplary embodiment includes a gasket that is deflectable into a collapsed orientation between first and second surfaces. The gasket may have a body of indefinite length and a base with a generally flat outer surface. The gasket may also include an upright portion extending generally upwardly away from the base such that the body has a generally inverted T-shaped profile collectively defined by the base and the upright portion. There may be one or more perforations adjacent the intersection of the upright portion and the base. The gasket may be deflectable between the first and second surfaces into the collapsed orientation characterized in that the upright portion bends generally downwardly towards the base with substantially continuous contact being maintained between the outer surface of the base and the second surface.

### CROSS-REFERENCE TO RELATED APPLICATION

This application claims the benefit of U.S. Provisional Application No. 60/947,271 filed Jun. 29, 2007. The disclosure of this application is incorporated herein by reference.

### FIELD

The present disclosure generally relates to electromagnetic interference gaskets.

### BACKGROUND

The statements in this section merely provide background information related to the present disclosure and may not constitute prior art.

During normal operation, electronic equipment can generate undesirable electromagnetic energy that can interfere with the operation of proximately located electronic equipment due to electromagnetic interference (EMI) transmission by radiation and conduction. The electromagnetic energy can be of a wide range of wavelengths and frequencies. To reduce the problems associated with EMI, sources of undesirable electromagnetic energy may be shielded and electrically grounded. Shielding can be designed to prevent both ingress and egress of electromagnetic energy relative to a housing or other enclosure in which the electronic equipment is disposed. Since such enclosures often include gaps or seams between adjacent access panels and around doors and connectors, effective shielding can be difficult to attain because the gaps in the enclosure permit transference of EMI therethrough. Further, in the case of electrically conductive metal enclosures, these gaps can inhibit the beneficial Faraday Cage Effect by forming discontinuities in the conductivity of the enclosure which compromise the efficiency of the ground conduction path through the enclosure. Moreover, by presenting an electrical conductivity level at the gaps that is significantly different from that of the enclosure generally, the gaps can act as slot antennae, resulting in the enclosure itself becoming a secondary source of EMI.

EMI gaskets have been developed for use in gaps and around doors to provide a degree of EMI shielding while permitting operation of enclosure doors and access panels and fitting of connectors. To shield EMI effectively, the gasket should be capable of absorbing or reflecting EMI as well as establishing a continuous electrically conductive path across the gap in which the gasket is disposed. These gaskets can also be used for maintaining electrical continuity across a structure and for excluding from the interior of the device such contaminates as moisture and dust. Once installed, the gaskets essentially close or seal any interface gaps and establish a continuous electrically-conductive path thereacross by conforming under an applied pressure to irregularities between the surfaces. Accordingly, gaskets intended for EMI shielding applications are specified to be of a construction that not only provides electrical surface conductivity even while under compression, but which also has a resiliency allowing the gaskets to conform to the size of the gap.

As used herein, the term “EMI” should be considered to generally include and refer to EMI emissions and RFI emissions, and the term “electromagnetic” should be considered to generally include and refer to electromagnetic and radio frequency from external sources and internal sources. Accordingly, the term shielding (as used herein) generally includes and refers to EMI shielding and RFI shielding, for example, to prevent (or at least reduce) ingress and egress of EMI and RFI relative to a housing or other enclosure in which electronic equipment is disposed.

### SUMMARY

According to various aspects, exemplary embodiments are provided of EMI shields, such as EMI gaskets. One exemplary embodiment includes a gasket that is deflectable into a collapsed orientation between first and second surfaces. The gasket has a body of indefinite length. The gasket may include a base with a generally flat outer surface and an upright portion extending generally upwardly away from the base such that the body has a generally inverted T-shaped profile collectively defined by the base and the upright portion. One or more perforations may be adjacent the intersection of the upright portion and the base. The gasket may be deflectable between the first and second surfaces into the collapsed orientation characterized in that the upright portion bends generally downwardly towards the base with substantially continuous contact being maintained between the outer surface of the base and the second surface.

Another exemplary embodiment includes a fabric-over-foam gasket for interposition between first and second surfaces. The gasket includes a body of indefinite length, a resilient foam core, and an outer electrically-conductive fabric disposed generally about and coupled to the resilient foam core. The body may have a first portion, a second portion, and one or more perforations adjacent the intersection of the first and second portions. The one or more perforations may be configured for helping an outer surface portion of the body maintain substantially continuous contact with the second surface when the gasket is compressively sandwiched under pressure between the first and second surfaces with the first surface compressively engaging the gasket's first portion in a direction generally towards the gasket's second portion.

Additional aspects relate to methods of making fabric-over-foam gaskets for interposition between first and second surfaces, such as a gasket including a body of indefinite length and first and second portions with a bending line generally therebetween. In one exemplary embodiment, a method generally includes forming one or more perforations adjacent the bending line. The one or more perforations may be configured for helping an outer surface portion of the body maintain substantially continuous contact with the second surface when the gasket is compressively sandwiched under pressure between the first and second surfaces with the first surface compressively engaging the gasket's first portion in a direction generally towards the gasket's second portion.

Other aspects relate to methods of providing electromagnetic shielding for a gap between first and second surfaces with a gasket. The gasket may have a body of indefinite length. The gasket body may have a first portion, a second portion extending generally away from the first portion, and one or more perforations generally between the first and second portions. In one exemplary embodiment, a method generally includes installing a gasket between the first and second surfaces such that the gasket is compressively sandwiched under pressure therebetween with the first surface applying a compressive force against the gasket's second portion in a direction generally towards the gasket's first portion. The one or more perforations may help the outer surface of the first portion maintain substantially continuous contact with the first surface as the second portion moves generally downwardly towards the first portion when the gasket is deflected into a collapsed orientation between the first and second surfaces.

Further aspects and features of the present disclosure will become apparent from the detailed description provided hereinafter. In addition, any one or more aspects of the present disclosure may be implemented individually or in any combination with any one or more of the other aspects of the present disclosure. It should be understood that the detailed description and specific examples, while indicating exemplary embodiments of the present disclosure, are intended for purposes of illustration only and are not intended to limit the scope of the present disclosure.

### DRAWINGS

The drawings described herein are for illustration purposes only and are not intended to limit the scope of the present disclosure in any way.

FIG. 1 is a perspective view of an exemplary fabric-over-foam EMI gasket having a generally T-shaped profile with perforations at about the interface of the upright portion and base thereof according to exemplary embodiments of the present disclosure;

FIG. 2 is a side view of the fabric-over-foam EMI gasket shown in FIG. 1;

FIG. 3 is a perspective view illustrating the fabric-over-foam gasket show in FIGS. 1 and 2 being compressed between generally parallel and opposite substrate surfaces with the gasket's base remaining substantially flat and flush against the lower substrate surface;

FIG. 4 is a perspective view of a fabric-over-foam gasket (without any perforations through the upright member) being compressed between generally parallel and opposite substrate surfaces and also illustrating the base lifting off of the lower substrate surface thus reducing the EMI shielding properties thereof; and

FIGS. 5 through 8 are exemplary line graphs illustrating shielding effectiveness (in decibels) versus frequency (in megahertz) for two different examples of fabric-over-foam gaskets.

### DETAILED DESCRIPTION

The following description is merely exemplary in nature and is in no way intended to limit the present disclosure, application, or uses. It should be understood that throughout the drawings, corresponding reference numerals indicate like or corresponding parts and features.

According to various aspects of the present disclosure, exemplary embodiments include EMI shields or gaskets (e.g., fabric-over-foam gaskets, etc.) that have first and second portions and one or more perforations (e.g., holes, openings, cutouts, slits, notches, etc.). The one or more perforations are specifically configured to help the outer surface of the first portion remain in substantial contact with and in conformance with the first surface, as the second surface contacts the second portion and causes the second portion to move (e.g., deflect, flex, deform, compress, etc.) generally downwardly towards the first surface. Helping the gasket maintain contact with the first surface, in turn, helps improve the electrical grounding between the gasket and the first and second surface. Accordingly, shielding effectiveness is improved due to the reduction of gapping between the gasket's base and the surface against which the gasket's base remains substantially in contact.

In some embodiments, the gasket includes an inverted or upside down generally T-shaped profile. Alternative embodiments may include other suitable cross-sectional profiles. Some embodiments include the perforations being substantially identical (e.g., all being generally rectangular, equally sized and oriented, etc.) to each other and/or evenly spaced apart along the intersection between the upright portion and the base. In various embodiments, perforations are provided at about the bending line defined between the base portion and the upwardly-extending portion, to flatten the folded part at the fold or bending line. Alternative embodiments may have perforations at additional or other locations besides the bending line or intersection of the upright portion and the base.

In various exemplary embodiments, a gasket is provided that is deflectable into a collapsed orientation between first and second surfaces. The gasket includes a body of indefinite length, a base (e.g., a generally flat leg or portion, etc.) having a generally flat outer surface, and an upright portion (e.g., generally vertical leg or member, etc.). The upright portion extends generally upwardly away from the base such that the body has a generally inverted T-shaped profile collectively defined by the base and the upright portion. One or more perforations (e.g., openings, holes, cutout, etc.) are provided, which may be adjacent, at, or about at the intersection or fold line of the upright portion and the base. Alternative embodiments may have perforations at alternative or additional locations. The gasket is deflectable between the first and second surfaces into the collapsed orientation characterized in that the upright portion bends, folds, collapses, transitions, moves, etc. generally downwardly towards the base with substantially continuous contact being maintained between the outer surface of the base and the second surface. In some embodiments, the outer surface of the base remains in conformance with the second surface. For example, some embodiment include the gasket's base being adhered (e.g., adhesively bonded, etc.) to the first surface with an upright portion of the gasket bending at the base to allow the gasket to thereby fit into a reduced application area.

In another exemplary embodiment, there is provided a fabric-over-foam gasket for interposition between first and second surfaces. The gasket includes a body of indefinite length with a resilient foam core and an outer electrically-conductive fabric. The electrically-conductive fabric is disposed generally about and coupled (e.g., adhesively bonded, etc.) to the resilient foam core. The body has a first portion, a second portion, and one or more perforations adjacent, at, and/or along the intersection of the first and second portions. The one or more perforations are configured to provide for helping an outer surface portion of the body maintain substantially continuous contact with the second surface when the gasket is compressively interposed sandwiched under pressure between the first and second surfaces with the first surface compressively engaging and applying a compressive force to the gasket's first portion in a direction generally towards the gasket's second portion. The body may have a generally inverted T-shaped profile or other suitable cross-sectional profile.

Other embodiments include methods of making gaskets (e.g., fabric-over-foam gaskets, etc.), which may later be interposed or sandwiched between first and second surfaces. The gasket may include a body of indefinite length with first and second portions having an intersection, bending line, or folding line generally therebetween. In one particular example, the method generally includes forming one or more perforations adjacent, at, and/or along the bending line. The one or more perforations are specifically configured for helping an outer surface portion of the body maintain substantially continuous contact with the second surface when the gasket is compressively sandwiched under pressure between the first and second surfaces. This may occur when the first surface compressively engages the gasket's first portion in a direction generally towards the gasket's second portion. The method may also include forming the body of the gasket by wrapping an electrically-conductive fabric layer generally around a resilient foam core. The fabric may be adhered or coupled to the resilient foam core with a pressure sensitive adhesive or other suitable adhesive. The one or more perforations may be formed by feeding the body of the gasket into a rotary die cutter. A gasket formed by this method may include a generally inverted T-shaped profile or other suitable profile shape.

Other embodiments include methods of providing electromagnetic shielding for a gap between first and second surfaces by using a gasket having a body of indefinite length, a first portion, a second portion extending generally away from the first portion, and one or more perforations generally between the first and second portions. In one particular example, the method generally includes installing the gasket between the first and second surfaces such that the gasket is compressively sandwiched under pressure therebetween with the first surface applying a compressive force against the gasket's second portion in a direction generally towards the gasket's first portion. The one or more perforations help the outer surface of the first portion maintain substantially continuous contact with the first surface as the second portion moves generally downwardly towards the first portion when the gasket is deflected into a collapsed orientation between the first and second surfaces. The gasket used in this method may be a fabric-over-foam gasket having a generally inverted T-shaped profile or other suitable profile shape. The one or more perforations may be disposed along the intersection of the first and second portions such that the first portion bends along the intersection of the first and second portions. The method may further include adhering the outer surface of the first portion to the first surface. The method may also include compressing the gasket between the first surface and the second surface, whereby the second surface contacts the second portion to forcibly bend the second portion downwardly towards the first portion along the intersection of the first and second portions.

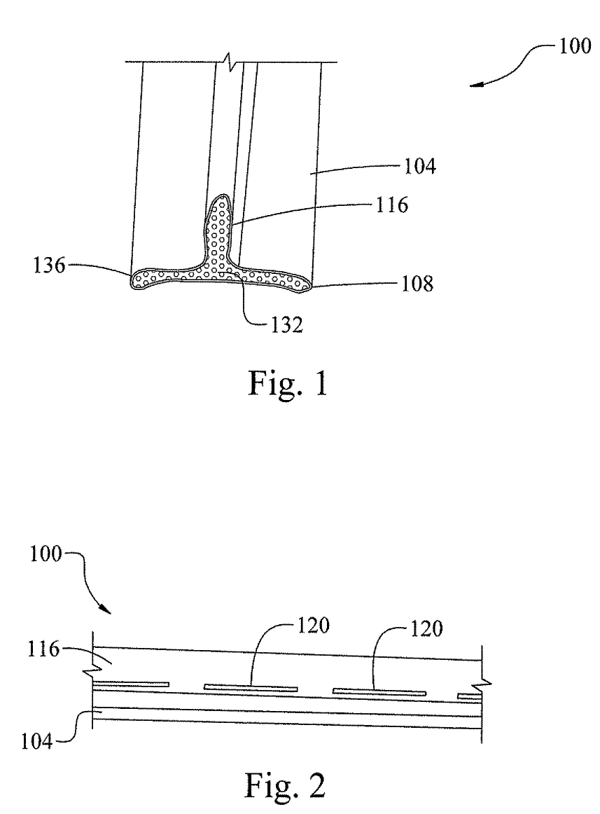

FIGS. 1 through 3 illustrate an exemplary EMI gasket 100 embodying one or more aspects of the present disclosure. As shown in FIG. 1, the gasket 100 includes a body 104 of indefinite length. The gasket also includes a base 108 having a generally flat outer surface 112. An upright portion 116 extends generally upwardly away from the base 108 such that the body 104 has a generally inverted T-shaped profile collectively defined by the base 108 and the upright portion 116, when the gasket 100 is free-standing or uncompressed as shown in FIG. 1. Alternatively, other suitable shapes may be used for the gasket profile. embodiments may include

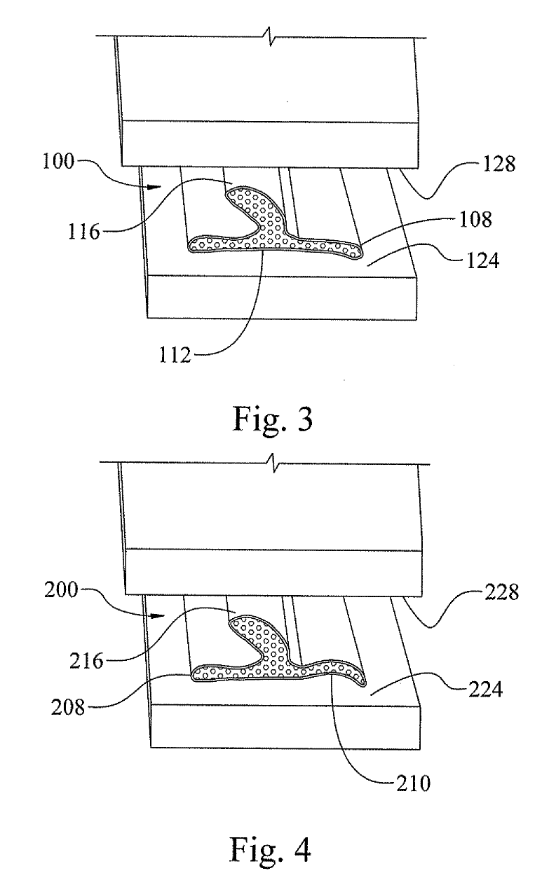

As shown in FIG. 2, the gasket 100 includes perforations 120 along and adjacent the intersection or fold line of the upright portion 116 and the base 108. Alternative embodiments may have one or more perforations at other locations.

With continued reference to FIG. 2, the illustrated perforations 120 are generally rectangular in shape and are about equally sized. In addition, the perforations 120 are about evenly or equally spaced apart. In other embodiments, a gasket may include more or less perforations and/or in other configurations (e.g., different shapes. sizes, other locations, etc.).

In this particular embodiment, the perforations 120 are formed such that they extend completely through upright portion 116 from one side to the other. By way of example, the perforations 120 may be formed by a rotary die cutter. Alternatively, other processes may be used to form one or more perforations extending completely through or only partially through a gasket.

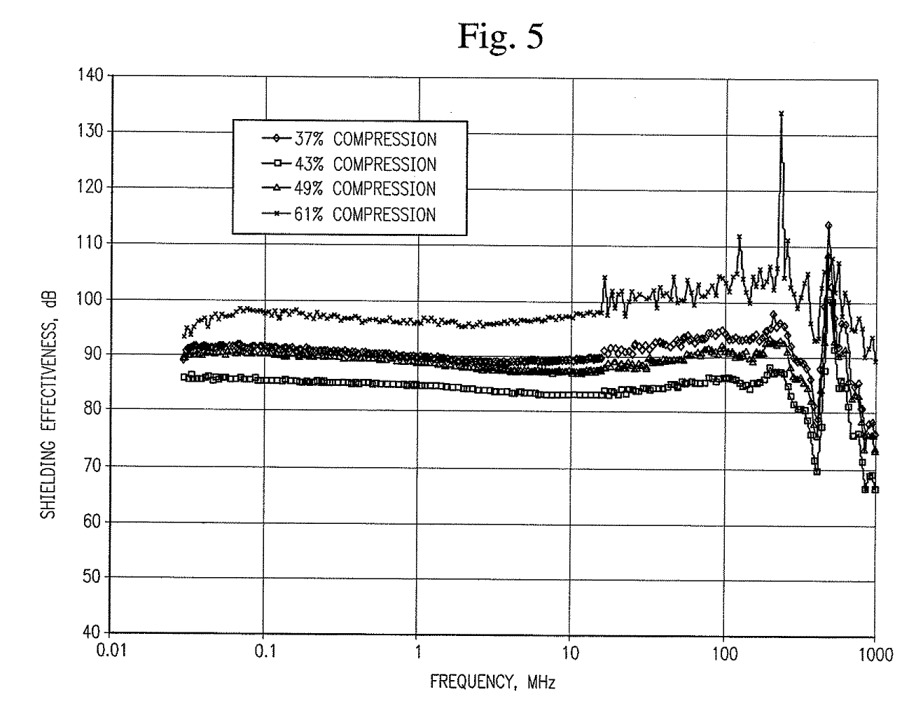

As shown in FIG. 3, the gasket 100 may be positioned within a gap defined by first and second surfaces 124, 128 such that the gasket is deflected, deformed, or compressed into the collapsed orientation. The collapsed orientation shown in FIG. 3 is characterized in that the upright portion 116 bends, folds, collapses, transitions, moves, etc. generally downwardly towards the base 108. Also shown in FIG. 3, the outer surface 108 of the base 108 remains in substantially continuous contact and in conformance with the surface 124. Depending on the particular end-use or application, the gasket's base 108 may be adhered (e.g., adhesively bonded, etc.) to the surface 124, such that other surface 128 may contact the upright portion 116 of the gasket 100 and cause the upright portion 116 to bend. The bending of the upright portion 116 provides the gasket 100 with a reduced height, thereby allowing the gasket 100 to fit into a reduced application area. The compression of the gasket 100 between the two surfaces 124, 128 preferably helps the gasket 100 establish electrical conductivity with the surfaces 124,128 sufficient for EMI shielding performance.

In some preferred embodiments, the gasket 100 is a fabric-over-foam gasket with a resilient core member 132 (e.g., compressible foam, etc.) and an electrically-conductive outer fabric layer 136 coupled to the resilient core member 132. In one preferred embodiment, the outer fabric layer 136 is a fabric material coated with nickel/copper, the resilient foam core 132 comprises polyurethane foam, a pressure sensitive adhesive is used for attached the fabric to the polyurethane core. Alternative embodiments may include other suitable materials for the core, outer layer, and/or adhesive.

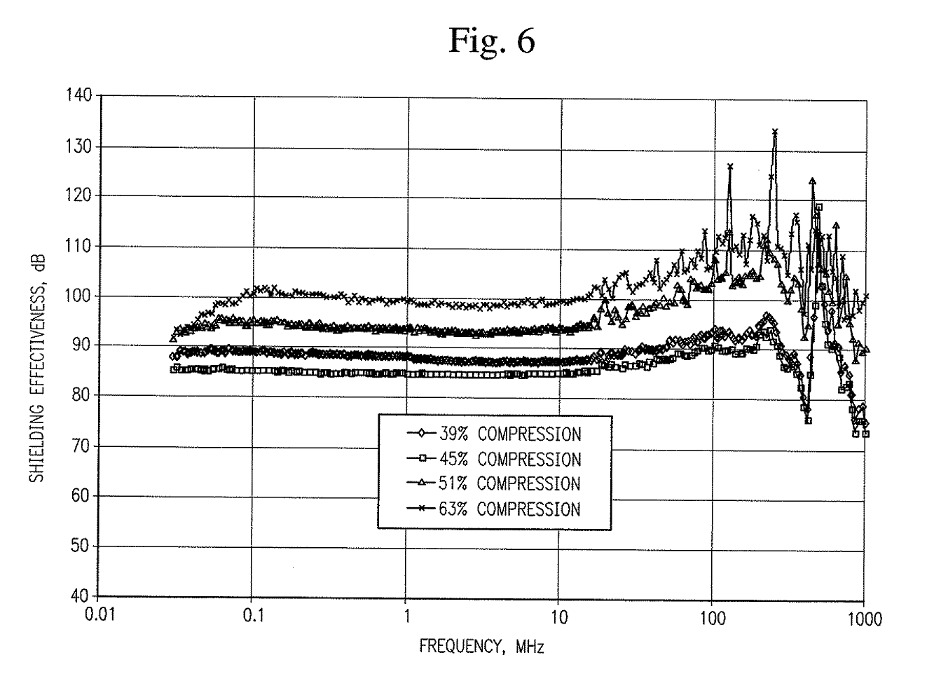

As shown in FIG. 3, the perforations 120 fully penetrate and pass completely through the upright leg 116 at about the intersection of the upright leg 116 and the base 108. The perforations 120 preferably allow the upright leg 116 to bend while helping the base 108 remain in substantial contact with the surface 124. With this reduction in gapping, the gasket 100 is able to provide better EMI shielding than the non-perforated gasket 200 (FIG. 4), which does not include any perforations along the intersection of the upright leg 216 and the base 208. As shown in FIG. 4, a portion 210 of the gasket's base 208 has begun to lift off of the surface 224 and lose contact therewith, as the upright leg 216 is moved downwardly towards the base 208 by way of the compressive force applied by the surface 228 to the upright leg 216.

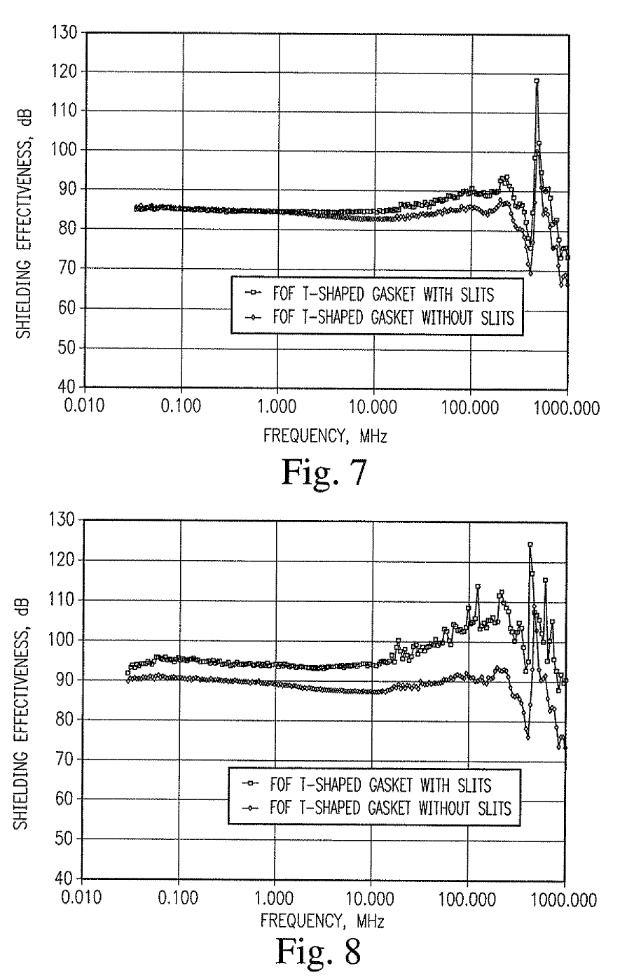

FIGS. 5 through 8 are exemplary line graphs illustrating shielding effective (in decibels) versus frequency (in megahertz). The testing performed to obtain the data depicted in FIGS. 5 through 8 will be explained. This testing and results depicted in FIGS. 5 through 8 are provided for purpose of illustration only and not for purposes of limitations, as other embodiments may be configured to provide different levels of shielding effectiveness than what is shown in any one or more of FIGS. 5 through 8.

The exemplary testing was performed to determine shielding effectiveness over a range of compressed heights of two fabric-over-foam gasket samples, both having a generally inverted T-shaped profile defined by a generally horizontal base and an upwardly extending vertical fin. Each gasket sample was approximately 4.6 millimeters tall with a base width of approximately 6.4 millimeters. One notable difference between the two test specimens, however, was that one gasket had slits or perforations in the fabric at about the intersection of the base and the vertical fin. The other gasket sample, however, did not include any such slits or perforations.

For this exemplary series of testing, transfer impedance was used as the measure of shielding effectiveness. The transfer impedance measurements were made using a transfer impedance fixture and a network analyzer with an added preamplifier. The frequency range of the transfer impedance measurements was thirty kilohertz to one gigahertz. In measurements of the range and repeatability of transfer impedance measurements performed with this instrumentation (i.e., the impedance fixture and network analyzer with an added preamplifier), it was observed that the maximum measurable transfer impedance was approximately one hundred thirty decibels with measurements repeatable within three to five decibels.

During the testing, the gasket samples were compressed between clean copper plates, which were pushed together by air pressure. Sample compression was controlled by plastic (electrically-insulating) compression stops at different compression heights.

FIG. 5 graphically illustrates the measured transfer impedance results for the gasket sample without any slits/perforations at four different compression heights, i.e., at 37%, 43%, 49%, and 61% compression. FIG. 6 graphically illustrates the measured transfer impedance results for the gasket sample having the slits/perforations at four different compression heights, i.e., at 39%, 45%, 51%, and 63% compression. It should be noted that resonances in the test fixture caused the relatively sharp changes in indicated shielding effectiveness at frequencies higher than 400 MHz.

Generally, the majority of gaskets demonstrate increasing shielding effectiveness (SE) as the percent compression increases. But as shown in FIG. 5, the unslitted gasket sample had a lower shielding effectiveness at 49% compression than at 43% compression. Likewise, FIG. 6 shows that the slitted/perforated gasket had a lower shielding effectiveness at 45% compression than at 39% compression.

As shown in FIGS. 5 and 6, the percent compression for the impedance transfer measurements were slightly different for the two types of gasket, due in part because of the relatively small height differentials being measured. That is, the compressed heights of the gasket samples were the same for the two materials, but the percentage compressions were slightly different (37% compared to 39%, 43% compared to 45%, 49% compared to 51%, and 61% compared 63%) they were slightly different percentages of the initial free-standing uncompressed heights of the two gasket samples.

Despite this minor discrepancy, the test results nevertheless accurately show improvement in shielding effectiveness that may be achieved by using a slitted/perforated gasket as compared to an unslitted gasket. For example, the shielding effectiveness results were similar for the two gaskets at about 45% compression as shown in FIG. 7. But when compression was increased to about 50%, the slitted/perforated gasket sample provided a much higher shielding effectiveness than the unslitted gasket sample, as shown in FIG. 8. Accordingly, these test results shown in FIGS. 5 through 8 illustrate that shielding effectiveness may be improved by using a fabric-over-foam inverted T-profiled gasket having slits in the fabric at the intersection of the base and the vertical fin, as compared to a fabric-over-foam inverted T-profiled gasket that did not include any slits. The extent of the improvement in shielding effectiveness was also found to vary depending on the percent compression, see, for example, the performance improvement shown at about 45% compression (FIG. 7) as compared to the higher performance improvement at about 50% compression (FIG. 8). As noted earlier, the testing and results depicted in FIGS. 5 through 8 are provided for purpose of illustration only and not for purpose of limitation, as other embodiments may be configured to provide different levels of shielding effectiveness and/or to be compressed at greater or lesser percentages than what is shown in any one or more of FIGS. 5 through 8.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “bottom” and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

When introducing elements or features and the exemplary embodiments, the articles “a”, “an”, “the” and “said” are intended to mean that there are one or more of such elements or features. The terms “comprising”, “including” and “having” are intended to be inclusive and mean that there may be additional elements or features other than those specifically noted. It is further to be understood that the method steps, processes, and operations described herein are not to be construed as necessarily requiring their performance in the particular order discussed or illustrated, unless specifically identified as an order of performance. It is also to be understood that additional or alternative steps may be employed.

The description of the disclosure is merely exemplary in nature and, thus, variations that do not depart from the gist of the disclosure are intended to be within the scope of the disclosure. Such variations are not to be regarded as a departure from the spirit and scope of the disclosure.

What is claimed is:

1. A gasket deflectable into a collapsed orientation between first and second surfaces, the gasket comprising a body of indefinite length and including:
a base having a generally flat outer surface;
an upright portion extending generally upwardly away from the base such that the body has a generally inverted T-shaped profile collectively defined by the base and the upright portion;
one or more perforations adjacent the intersection of the upright portion and the base;
the gasket being deflectable between the first and second surfaces into the collapsed orientation characterized in that the upright portion bends generally downwardly towards the base with substantially continuous contact being maintained between the outer surface of the base and the second surface.

2. The gasket of claim 1, wherein the one or more perforations are disposed along the intersection of the upright portion and the base, and wherein the gasket is deflectable between the first and second surfaces into the collapsed orientation characterized in that the upright portion bends along the intersection of the upright portion and the base generally downwardly towards the base with substantially continuous contact being maintained between an outer surface of the base and the second surface.

3. The gasket of claim 1, wherein the one or more perforations are configured for helping the outer surface of the base maintain substantially continuous contact with the second surface as the upright portion moves generally downwardly towards the base when the gasket is deflected into the collapsed orientation between the first and second surfaces.

4. The gasket of claim 1, wherein the one or more perforations include at least two perforations longitudinally spaced-apart along the intersection of the upright portion and the base.

5. The gasket of claim 4, wherein the two or more perforations are evenly spaced apart along the intersection.

6. The gasket of claim 1, wherein the one or more perforations are generally rectangular in shape.

7. The gasket of claim 1, wherein the one or more perforations include at least two substantially identical perforations.

8. The gasket of claim 1, wherein the one or more perforations extend completely through the upright portion.

9. The gasket of claim 1, wherein the body of the gasket comprises a resilient core member and an electrically-conductive outer layer coupled to the resilient core member.

10. The gasket of claim 9, wherein the outer electrically-conductive layer comprises fabric, and wherein the resilient core member comprises resiliently compressible foam.

11. The gasket of claim 9, wherein the outer electrically-conductive layer comprises fabric coated with nickel and/or copper, wherein the resilient core member comprises polyurethane foam, and further comprising a pressure sensitive adhesive disposed between the fabric and the foam.

12. The gasket of claim 1, wherein, when the gasket is deflected into the collapsed orientation between the first and second surfaces, the one or more perforations reduce gapping between the outer surface of the base and the second surface to thereby improve shielding effectiveness.

13. A fabric-over-foam gasket for interposition between first and second surfaces, the gasket comprising a body of indefinite length and including a resilient foam core and an outer electrically-conductive fabric disposed generally about and coupled to the resilient foam core, the body having a first portion, a second portion, and one or more perforations adjacent the intersection of the first and second portions, the one or more perforations configured for helping an outer surface portion of the body maintain substantially continuous contact with the second surface when the gasket is compressively sandwiched under pressure between the first and second surfaces with the first surface compressively engaging the gasket's first portion in a direction generally towards the gasket's second portion.

14. The gasket of claim 13, wherein the first portion comprises a base having a generally flat lower surface and the second portion comprises at least one protruding member extends generally away from the base.

15. The gasket of claim 14, wherein the body has a generally inverted T-shaped profile collectively defined by the base and the protruding member.

16. The gasket of claim 14, wherein the gasket is deflectable between the first and second surfaces into the collapsed orientation characterized in that the protruding member bends along the intersection of the protruding member and the base generally downwardly towards the base with substantially continuous contact being maintained between the lower surface of the base and the second surface.

17. A method of making a fabric-over-foam gasket for interposition between first and second surfaces, the gasket including a body of indefinite length and first and second portions with a bending line generally therebetween, the method comprising forming one or more perforations adjacent the bending line, whereby the one or more perforations are configured for helping an outer surface portion of the body maintain substantially continuous contact with the second surface when the gasket is compressively sandwiched under pressure between the first and second surfaces with the first surface compressively engaging the gasket's first portion in a direction generally towards the gasket's second portion.

18. The method of claim 17, further comprising forming the body of the gasket by wrapping an electrically-conductive fabric layer generally around a resilient foam core and adhering the electrically-conductive fabric layer to the resilient foam core with a pressure sensitive adhesive.

19. The method of claim 18, wherein forming the one or more perforations includes feeding the body of the gasket into a rotary die cutter.

20. The method of claim 17, wherein the gasket has a generally inverted T-shaped profile collectively defined by the first and second portions, and wherein the one or more perforations are disposed along the intersection of the first and second portions.

21. A method of providing electromagnetic shielding for a gap between first and second surfaces with a gasket having a body of indefinite length, the body having a first portion, a second portion extending generally away from the first portion, and one or more perforations generally between the first and second portions, the method comprising installing the gasket between the first and second surfaces such that the gasket is compressively sandwiched under pressure therebetween with the first surface applying a compressive force against the gasket's second portion in a direction generally towards the gasket's first portion, whereby the one or more perforations help the outer surface of the first portion maintain substantially continuous contact with the first surface as the second portion moves generally downwardly towards the first portion when the gasket is deflected into a collapsed orientation between the first and second surfaces.

22. The method of claim 21, wherein the gasket comprises a fabric-over-foam gasket having a generally inverted T-shaped profile collectively defined by the first and second portions, and wherein the one or more perforations are disposed along the intersection of the first and second portions such that the first portion bends along the intersection of the first and second portions.

23. The method of claim 21, wherein installing includes adhering the outer surface of the first portion to the first surface, and compressing the gasket between the first surface and the second surface, whereby the second surface contacts the second portion to forcibly bend the second portion downwardly towards the first portion along the intersection of the first and second portions.
